(19) United States
(12) Patent Application Publication
(10) Pub. No.: US 2012/0177846 A1
(43) Pub. Date: Jul. 12, 2012

(54) RADICAL STEAM CVD

(75) Inventors: DongQing Li, Fremont, CA (US); Jingmei Liang, San Jose, CA (US); Xiaolin Chen, San Ramon, CA (US); Nitin K. Ingle, San Jose, CA (US)

(73) Assignee: Applied Materials, Inc., Santa Clara, CA (US)

(21) Appl. No.: 13/236,388

(22) Filed: Sep. 19, 2011

Related U.S. Application Data
(60) Provisional application No. 61/430,620, filed on Jan. 7, 2011.

(51) Int. Cl. C23C 16/40; C23C 16/56; C23C 16/50

(52) U.S. Cl. 427/579

(57) ABSTRACT

Methods of forming silicon oxide layers are described. The methods include concurrently combining plasma-excited (radical) steam with an unexcited silicon precursor. Nitrogen may be supplied through the plasma-excited route (e.g. by adding ammonia to the steam) and/or by choosing a nitrogen-containing unexcited silicon precursor. The methods result in depositing a silicon-oxygen-and-nitrogen-containing layer on a substrate. The oxygen content of the silicon-oxygen-and-nitrogen-containing layer is then increased to form a silicon oxide layer which may contain little or no nitrogen. The increase in oxygen content may be brought about by annealing the layer in the presence of an oxygen-containing atmosphere and the density of the film may be increased further by raising the temperature even higher in an inert environment.

### CROSS-REFERENCES TO RELATED APPLICATIONS

This application claims the benefit of U.S. Provisional Application No. 61/430,620 by Li et al, filed Jan. 7, 2011 and titled “RADICAL STEAM CVD” which is incorporated herein in its entirety for all purposes.

### BACKGROUND OF THE INVENTION

Semiconductor device geometries have dramatically decreased in size since their introduction several decades ago. Modern semiconductor fabrication equipment routinely produces devices with 45 nm, 32 nm, and 28 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., SOG deposition techniques). These flowable precursors can flow into and fill very small substrate gaps without forming voids or weak seams. However, once these highly flowable materials are deposited, they have to be hardened into a solid dielectric material.

In many instances, the hardening process includes a heat treatment to remove carbon and hydroxyl groups from the deposited material to leave behind a solid dielectric such as silicon oxide. Unfortunately, the departing carbon and hydroxyl species often leave behind pores in the hardened dielectic that reduce the quality of the final material. In addition, the hardening dielectric also tends to shrink in volume, which can leave cracks and spaces at the interface of the dielectric and the surrounding substrate. In some instances, the volume of the hardened dielectric can decrease by 40% or more.

Thus, there is a need for new deposition processes and materials to form dielectric materials on structured substrates without generating voids, seams, or both, in substrate gaps and trenches. There is also a need for materials and methods of hardening flowable dielectric materials with a lower decrease in volume. This and other needs are addressed in the present application.

### BRIEF SUMMARY OF THE INVENTION

Methods of forming silicon oxide layers are described. The methods include concurrently combining plasma-excited (radical) steam with an unexcited silicon precursor. Nitrogen may be supplied through the plasma-excited route (e.g. by adding ammonia to the steam) and/or by choosing a nitrogen-containing unexcited silicon precursor. The methods result in depositing a silicon-oxygen-and-nitrogen-containing layer on a substrate. The oxygen content of the silicon-oxygen-and-nitrogen-containing layer is then increased to form a silicon oxide layer which may contain little or no nitrogen. The increase in oxygen content may be brought about by annealing the layer in the presence of an oxygen-containing atmosphere and the density of the film may be increased further by raising the temperature even higher in an inert environment.

Embodiments of the invention include methods of forming a silicon oxide layer on a substrate in a plasma-free substrate processing region in a substrate processing chamber. The methods include flowing an oxygen-containing precursor into a plasma region to produce a radical-oxygen precursor. The oxygen-containing precursor contains H₂O. The methods further include combining the radical-oxygen precursor with a silicon-containing precursor in the plasma-free substrate processing region. The silicon-containing precursor contains nitrogen. The methods further include depositing a silicon-oxygen-and-nitrogen-containing layer on the substrate.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components.

FIG. 1 is a flowchart illustrating selected steps for making a silicon oxide film according to embodiments of the invention.

FIG. 2 is another flowchart illustrating selected steps for forming a silicon oxide film using a chamber plasma region according to embodiments of the invention.

FIG. 3 shows a substrate processing system according to embodiments of the invention.

FIG. 4A shows a substrate processing chamber according to embodiments of the invention.

FIG. 4B shows a showerhead of a substrate processing chamber according to embodiments of the invention.

### DETAILED DESCRIPTION OF THE INVENTION

Methods of forming silicon oxide layers are described. The methods include concurrently combining plasma-excited (radical) steam with an unexcited silicon precursor.

Nitrogen may be supplied through the plasma-excited route (e.g. by adding ammonia to the steam) and/or by choosing a nitrogen-containing unexcited silicon precursor. The methods result in depositing a silicon-oxygen-and-nitrogen-containing layer on a substrate. The oxygen content of the silicon-oxygen-and-nitrogen-containing layer is then increased to form a silicon oxide layer which may contain little or no nitrogen. The increase in oxygen content may be brought about by annealing the layer in the presence of an oxygen-containing atmosphere and the density of the film may be increased further by raising the temperature even higher in an inert environment.

Without binding the coverage of the claims to hypothetical mechanisms which may or may not be entirely correct, a discussion of some details may prove beneficial. A silicon-and-nitrogen-containing film may be formed by combining a radical nitrogen precursor with a silicon-and-nitrogen-containing precursor in a plasma free region housing a deposition substrate. This deposition method may result in a relatively open network film which allows the silicon-oxygen-and-nitrogen-containing film to be converted to silicon oxide by curing the film in ozone at a low temperature and subsequently annealing the film in an oxygen-containing atmosphere at higher temperature. The open network may allow the ozone to penetrate more deeply within the film, extending the oxide conversion in the direction of the substrate. The radical nitrogen component may be replaced by plasma effluents of moisture (H₂O) which has been found to also produce initially-flowable films. The benefits of using H₂O (aka steam) plasma effluents have been found to include a higher film deposition rate and a lower plasma power in disclosed embodiments. Steam plasma effluents may be referred to herein as radical-oxygen. The presence of oxygen in the as-deposited film reduces the quantity of oxygen which must flow through the open network in order to convert the film to silicon oxide during subsequent processing. The exposure to radical-oxygen may serve to homogenize the oxygen content, lower the refractive index, increase the deposition rate and may allow the cure step to be reduced or even eliminated.

### Exemplary Silicon Oxide Formation Process

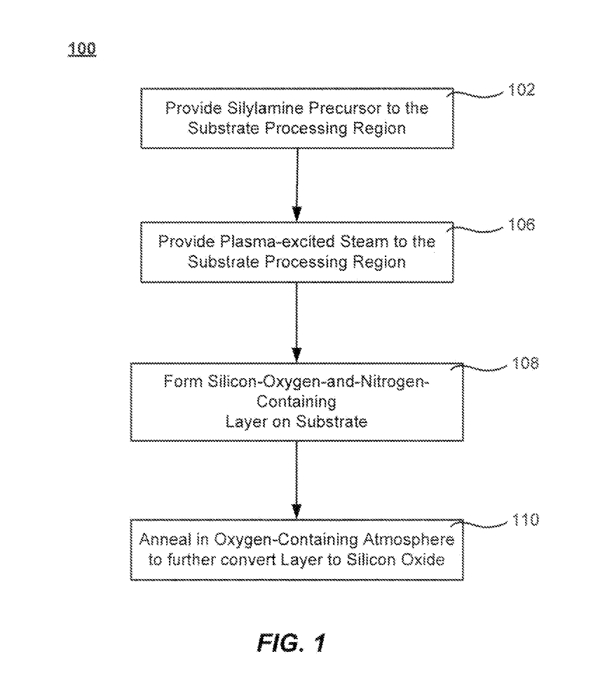

FIG. 1 is a flowchart showing selected steps in methods 100 of making silicon oxide films according to embodiments of the invention. The method 100 includes providing a silylamine precursor to a plasma-free substrate processing region 102. Generally speaking, the precursor may be a silicon-and-nitrogen-containing precursor, a silicon-and-hydrogen-containing precursor, or a silicon-nitrogen-and-hydrogen-containing precursor, among other classes of silicon precursors. The silicon-precursor may be oxygen-free and/or carbon-free.

Specific examples of silylamine precursors include H₂N(SiH₃) (i.e. MSA), HN(SiH₃)₂ (i.e. DSA), and N(SiH₃)₃ (i.e. TSA), among other silyl-amines. The flow rates of a silylamine precursor may be greater than or about 200 sccm, greater than or about 300 sccm, greater than or about 500 sccm or greater than or about 700 sccm in different embodiments. All flow rates given herein refer to a dual chamber 300 mm substrate processing system. Single wafer systems would require half these flow rates and other wafer sizes would require flow rates scaled by the processed area. These silylamines may be mixed with additional gases that may act as carrier gases, reactive gases, or both. Examples of additional gases include H₂, N₂, NH₃, He, and Ar, among other gases. Additional examples of carbon-free silicon precursors include silane (SiH₄) either alone or mixed with other silicon-containing gases (e.g., N(SiH₃)₃), hydrogen (e.g., H₂), and/or nitrogen (e.g., N₂, NH₃). Carbon-free silicon precursors may also include disilane, trisilane, even higher-order silanes, and chlorinated silanes, alone or in combination with one another or the previously mentioned carbon-free silicon precursors.

A radical-oxygen precursor, created by flowing steam through a plasma excitation region, is also provided to the plasma-free substrate processing region 106. The radical-oxygen precursor is an oxygen-radical-containing precursor that was generated outside the plasma-free substrate processing region from a more stable oxygen-containing precursor, steam. Steam, H₂O and moisture will be used interchangeably herein. The flow rate of the steam may be greater than or about 50 sccm, greater than or about 100 sccm, greater than or about 150 sccm, greater than or about 200 sccm or greater than or about 250 sccm in different embodiments. The flow rate of the steam may be less than or about 600 sccm, less than or about 500 sccm, less than or about 400 sccm or less than or about 300 sccm in different embodiments. Any of these upper bounds may be combined with any of the lower bounds to form additional ranges for the flow rates of the steam according to additional disclosed embodiments. The radical-oxygen precursor is transported into the plasma-free substrate processing region.

Steam may be combined with a relatively stable nitrogen additive in a chamber plasma region or a remote plasma system (RPS) outside the processing chamber to form the radical-oxygen precursor. The relatively stable nitrogen additive may also be a mixture comprising NH₃ & N₂, NH₃ & H₂, NH₃ & N₂ & H₂ and N₂ & H₂, in different embodiments. Hydrazine may also be used in place of or in combination with NH₃ in the mixtures with N₂ and H₂. A steam may be accompanied by other stable oxygen-containing precursor compounds including O₂, O₃, H₂O₂, NO, NO₂ and/or N₂O which are also activated in the chamber plasma region or a remote plasma system (RPS) outside the processing chamber to form the radical-oxygen precursor.

In the substrate processing region, the flow of the radical-oxygen precursor mixes with the silylamine (or another silicon precursor as described above) which react to deposit a silicon-oxygen-and-nitrogen-containing film on the deposition substrate 108. The silylamine has not been appreciably excited by plasma. The deposited silicon-oxygen-and-nitrogen-containing film may deposit conformally for low deposition rates. In other embodiments, the deposited silicon-oxygen-and-nitrogen-containing film has flowable characteristics unlike conventional silicon nitride (Si₃N₄) film deposition techniques. The flowable nature of the formation allows the film to flow into narrow gaps trenches and other structures on the deposition surface of the substrate. The silicon-oxygen-and-nitrogen-containing film is initially flowable following deposition, in embodiments, and this may hold true at relatively low substrate temperatures. Silicon-oxygen-and-nitrogen-containing films are flowable below or about 200° C., 150° C., 100° C. and even 50° C. in embodiments of the invention.

The flowability may be due to a variety of properties which result from mixing a radical precursor with the silicon precursor. These properties may include a significant hydrogen component in the deposited film and/or the presence of short chained polysilazane polymers. These short chains grow and network to form more dense dielectric material during and after the formation of the film. For example the deposited film may have a silazane-type, Si—NH—Si backbone (i.e., a Si—N—H film). In embodiments where the silicon precursor and the radical precursor are carbon-free, the deposited silicon-oxygen-and-nitrogen-containing film is also substantially carbon-free. Of course, “carbon-free” does not necessarily mean the film lacks even trace amounts of carbon. Carbon contaminants may be present in the precursor materials that find their way into the deposited silicon-oxygen-and-nitrogen-containing film. The amount of these carbon impurities however are much less than would be found in a silicon precursor having a carbon moiety (e.g., TEOS, TMDSO, etc.).

Following the deposition of the silicon-oxygen-and-nitrogen-containing layer, the deposition substrate may be annealed in an oxygen-containing atmosphere 110. The deposition substrate may remain in the same substrate processing region used for curing when the oxygen-containing atmosphere is introduced, or the substrate may be transferred to a different chamber where the oxygen-containing atmosphere is introduced. The oxygen-containing atmosphere may include one or more oxygen-containing gases such as molecular oxygen (O₂), ozone (O₃), water vapor (H₂O), hydrogen peroxide (H₂O₂) and nitrogen-oxides (NO, NO₂, etc.), among other oxygen-containing gases. The oxygen-containing atmosphere may also include radical-oxygen and hydroxyl species such as atomic oxygen (O), hydroxides (OH), etc., that may be generated remotely and transported into the substrate chamber. Ions of oxygen-containing species may also be present. The oxygen anneal temperature of the substrate may be less than or about 1100° C., less than or about 1000° C., less than or about 900° C. or less than or about 800° C. in different embodiments. The temperature of the substrate may be greater than or about 500° C., greater than or about 600° C., greater than or about 700° C. or greater than or about 800° C. in different embodiments. Once again, any of the upper bounds may be combined with any of the lower bounds to form additional ranges for the substrate temperature according to additional disclosed embodiments.

A plasma may or may not be present in the substrate processing region during the oxygen anneal. The oxygen-containing gas entering the CVD chamber may include one or more compounds that have been activated (e.g., radicalized, ionized, etc.) before entering the substrate processing region. For example, the oxygen-containing gas may include radical-oxygen species, radical hydroxyl species, etc., activated by exposing more stable precursor compounds through a remote plasma source or through a chamber plasma region separated from the substrate processing region by a showerhead. The more stable precursors may include water vapor and hydrogen peroxide (H₂O₂) that produce hydroxyl (OH) radicals and ions, and molecular oxygen and/or ozone that produce atomic oxygen (O) radicals and ions.

A curing operation may be unnecessary given the significant oxygen content already present in the silicon-oxygen-and-nitrogen-containing film. However, if desired, a curing operation would be introduced prior to the annealing operation. During a cure, the deposition substrate may remain in the substrate processing region for curing, or the substrate may be transferred to a different chamber where the ozone-containing atmosphere is introduced. The curing temperature of the substrate may be less than or about 400° C., less than or about 300° C., less than or about 250° C., less than or about 200° C. or less than or about 150° C. in different embodiments. The temperature of the substrate may be greater than or about room temperature, greater than or about 50° C., greater than or about 100° C., greater than or about 150° C. or greater than or about 200° C. in different embodiments. Any of the upper bounds may be combined with any of the lower bounds to form additional ranges for the substrate temperature according to additional disclosed embodiments. No plasma is present in the substrate processing region, in embodiments, to avoid generating atomic oxygen which may close the near surface network and thwart subsurface oxidation. The flow rate of the ozone into the substrate processing region during the cure step may be greater than or about 200 sccm, greater than or about 300 sccm or greater than or about 500 sccm. The partial pressure of ozone during the cure step may be greater than or about 10 Torr, greater than or about 20 Torr or greater than or about 40 Torr. Under some conditions (e.g. between substrate temperatures from about 100° C. to about 200° C.) the conversion has been found to be substantially complete so a relatively high temperature anneal in an oxygen-containing environment may be unnecessary in embodiments.

The oxygen-containing atmospheres of both the curing and oxygen anneal provide oxygen to convert the silicon-oxygen-and-nitrogen-containing film into the silicon oxide (SiO₂) film. As noted previously, a lack of carbon in the silicon-oxygen-and-nitrogen-containing film, in some embodiments, results in significantly fewer pores formed in the final silicon oxide film. It also results in less volume reduction (i.e., shrinkage) of the film during the conversion to the silicon oxide. For example, where a silicon-nitrogen-carbon layer formed from carbon-containing silicon precursors may shrink by 40 vol. % or more when converted to silicon oxide, the substantially carbon-free silicon-oxygen-and-nitrogen films may shrink by about 15 vol. % or less.

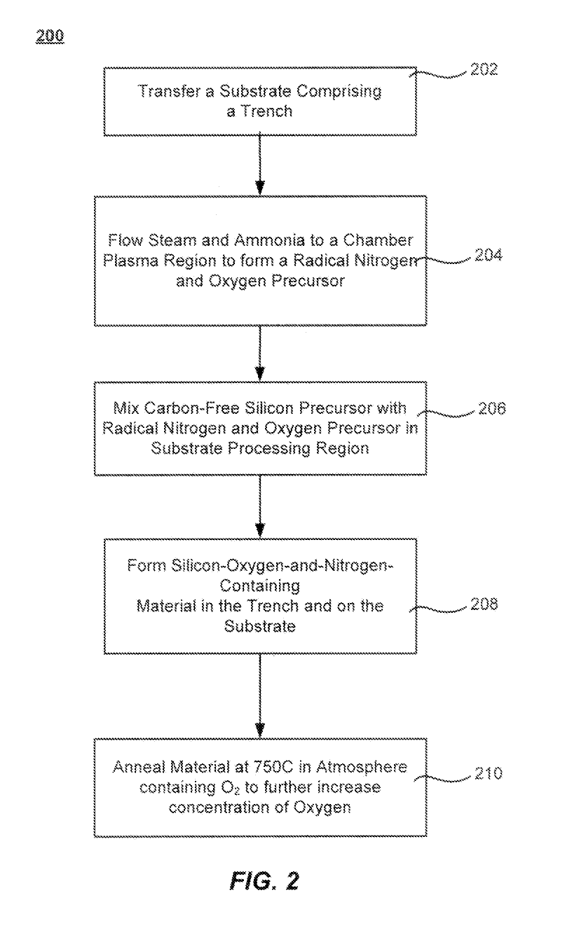

Referring now to FIG. 2, another flowchart is shown illustrating selected steps in methods 200 for forming a silicon oxide film in a substrate gap (a trench) according to embodiments of the invention. The method 200 includes transferring a substrate comprising a gap into a substrate processing region (operation 202). The substrate may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., about 90 nm, 65 nm, 45 nm, 32 nm, 22 nm, 16 nm, etc.).

Concurrent flows of a stable nitrogen precursor (ammonia) and a stable oxygen precursor (H₂O) into a chamber plasma region form what is referred to herein as a radical-oxygen precursor (operation 204). A carbon-free silicon precursor which has not been significantly excited by plasma is mixed with the radical- oxygen precursors in the plasma-free substrate processing region (operation 206). A flowable silicon-oxygen-and-nitrogen-containing layer is deposited on the substrate (operation 208). Because the layer is flowable, it can fill the gaps (aka trenches) despite their high aspect ratios without creating voids or weak seams around the center of the filling material. For example, a depositing flowable material is less likely to prematurely clog the top of a gap before it is completely filled to leave a void in the middle of the gap.

The as-deposited silicon-oxygen-and-nitrogen-containing layer may then be annealed (e.g. at 750° C.) in an oxygen-containing atmosphere (operation 210) to transition the silicon-oxygen-and-nitrogen-containing layer to silicon oxide. Temperatures and other process parameters for this operation and others in FIG. 2 have the same upper and/or lower limits as recited during the description of FIG. 1. A further anneal (not shown) may be carried out in an inert environment at a higher substrate temperature in order to densify the silicon oxide layer. Again, a curing step may be conducted to assist in the conversion to silicon oxide and would occur between the formation of the film (operation 206) and the annealing operation 210.

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

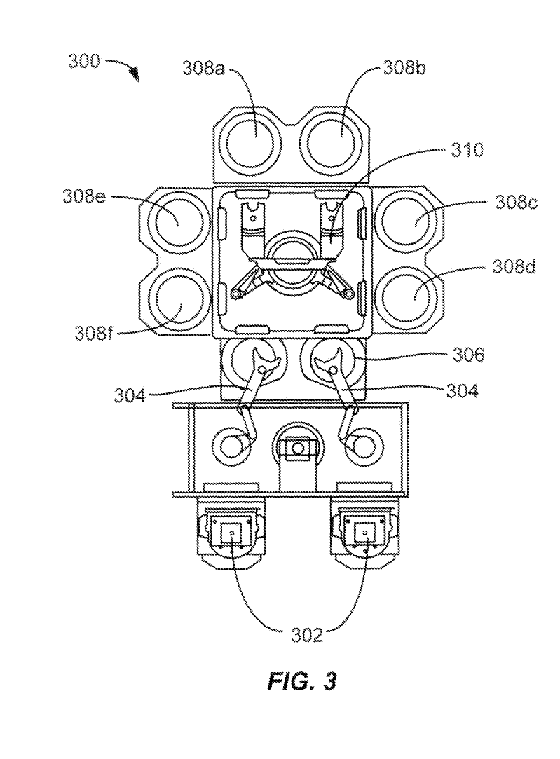

Embodiments of the deposition systems may be incorporated into larger fabrication systems for producing integrated circuit chips. FIG. 3 shows one such system 300 of deposition, baking and curing chambers according to disclosed embodiments. In the figure, a pair of FOUPs (front opening unified pods) 302 supply substrate substrates (e.g., 300 mm diameter wafers) that are received by robotic arms 304 and placed into a low pressure holding area 306 before being placed into one of the wafer processing chambers 308a-f. A second robotic arm 310 may be used to transport the substrate wafers from the holding area 306 to the processing chambers 308a-f and back.

The processing chambers 308a-f may include one or more system components for depositing, annealing, curing and/or etching a flowable dielectric film on the substrate wafer. In one configuration, two pairs of the processing chamber (e.g., 308c-d and 308e-f) may be used to deposit the flowable dielectric material on the substrate, and the third pair of processing chambers (e.g., 308a-b) may be used to anneal the deposited dielectic. In another configuration, the same two pairs of processing chambers (e.g., 308c-d and 308e-f) may be configured to both deposit and anneal a flowable dielectric film on the substrate, while the third pair of chambers (e.g., 308a-b) may be used for UV or E-beam curing of the deposited film. In still another configuration, all three pairs of chambers (e.g., 308a-f) may be configured to deposit and cure a flowable dielectric film on the substrate. In yet another configuration, two pairs of processing chambers (e.g., 308c-d and 308e-f) may be used for both deposition and UV or E-beam curing of the flowable dielectric, while a third pair of processing chambers (e.g. 308a-b) may be used for annealing the dielectric film. Any one or more of the processes described may be carried out on chamber(s) separated from the fabrication system shown in different embodiments.

In addition, one or more of the process chambers 308a-f may be configured as a wet treatment chamber. These process chambers include heating the flowable dielectric film in an atmosphere that include moisture. Thus, embodiments of system 300 may include wet treatment chambers 308a-b and anneal processing chambers 308c-d to perform both wet and dry anneals on the deposited dielectric film.

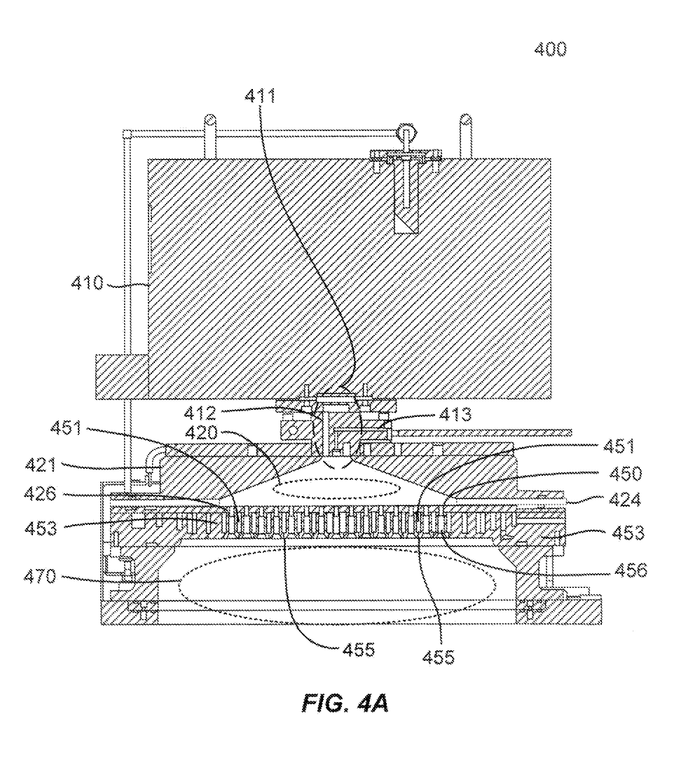

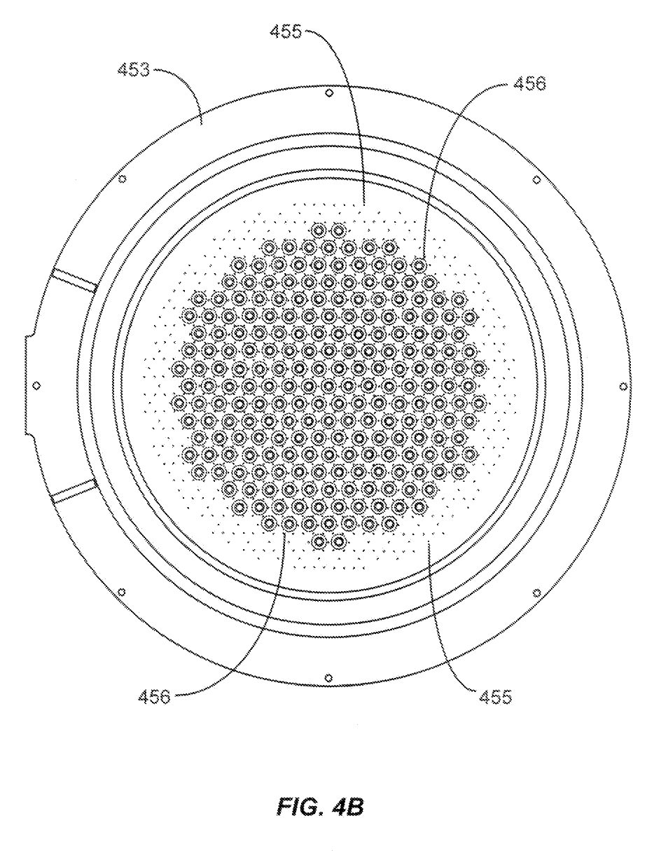

FIG. 4A is a substrate processing chamber 400 according to disclosed embodiments. A remote plasma system (RPS) 410 may process a gas which then travels through a gas inlet assembly 411. Two distinct gas supply channels are visible within the gas inlet assembly 411. A first channel 412 carries a gas that passes through the remote plasma system RPS 410, while a second channel 413 bypasses the RPS 400. The first channel 402 may be used for the process gas and the second channel 413 may be used for a treatment gas in disclosed embodiments. The lid (or conductive top portion) 421 and a perforated partition 453 are shown with an insulating ring 424 in between, which allows an AC potential to be applied to the lid 421 relative to perforated partition 453. The process gas travels through first channel 412 into chamber plasma region 420 and may be excited by a plasma in chamber plasma region 420 alone or in combination with RPS 410. The combination of chamber plasma region 420 and/or RPS 410 may be referred to as a remote plasma system herein. The perforated partition (also referred to as a showerhead) 453 separates chamber plasma region 420 from a substrate processing region 470 beneath showerhead 453. Showerhead 453 allows a plasma present in chamber plasma region 420 to avoid directly exciting gases in substrate processing region 470, while still allowing excited species to travel from chamber plasma region 420 into substrate processing region 470.

Showerhead 453 is positioned between chamber plasma region 420 and substrate processing region 470 and allows plasma effluents (excited derivatives of precursors or other gases) created within chamber plasma region 420 to pass through a plurality of through holes 456 that traverse the thickness of the plate. The showerhead 453 also has one or more hollow volumes 451 which can be filled with a precursor in the form of a vapor or gas (such as a silicon-containing precursor) and pass through small holes 455 into substrate processing region 470 but not directly into chamber plasma region 420. Showerhead 453 is thicker than the length of the smallest diameter 450 of the through-holes 456 in this disclosed embodiment. In order to maintain a significant concentration of excited species penetrating from chamber plasma region 420 to substrate processing region 470, the length 426 of the smallest diameter 450 of the through-holes may be restricted by forming larger diameter portions of through-holes 456 part way through the showerhead 453. The length of the smallest diameter 450 of the through-holes 456 may be the same order of magnitude as the smallest diameter of the through-holes 456 or less in disclosed embodiments.

In the embodiment shown, showerhead 453 may distribute (via through holes 456) process gases which contain oxygen, hydrogen and/or nitrogen and/or plasma effluents of such process gases upon excitation by a plasma in chamber plasma region 420. In embodiments, the process gas introduced into the RPS 410 and/or chamber plasma region 420 through first channel 412 may contain one or more of H₂, N₂, NH₃ and N₂H₄. The process gas may also include a carrier gas such as helium, argon, nitrogen (N₂), etc. Water (aka moisture, steam or H2O) may be combined with other oxygen sources, such as oxygen (O₂) or ozone (O₃), and delivered through second channel 413 to grow silicon-oxygen-and-nitrogen-containing films as described herein. Alternatively, the oxygen-containing gas and the nitrogen-and-hydrogen-containing gas may be combined and both flow through first channel 412 or second channel 413. The second channel 413 may also deliver a carrier gas and/or a film-curing gas used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 456 may be between about 60 and about 2000. Through-holes 456 may have a variety of shapes but are most easily made round. The smallest diameter 450 of through holes 456 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 455 used to introduce a gas into substrate processing region 470 may be between about 100 and about 5000 or between about 500 and about 2000 in different embodiments. The diameter of the small holes 455 may be between about 0.1 mm and about 2 mm.

FIG. 4B is a bottom view of a showerhead 453 for use with a processing chamber according to disclosed embodiments. Showerhead 453 corresponds with the showerhead shown in FIG. 4A. Through-holes 456 are depicted with a larger inner-diameter (ID) on the bottom of showerhead 453 and a smaller ID at the top. Small holes 455 are distributed substantially evenly over the surface of the showerhead, even amongst the through-holes 456 which helps to provide more even mixing than other embodiments described herein.

An exemplary film is created on a substrate supported by a pedestal (not shown) within substrate processing region 470 when plasma effluents arriving through through-holes 456 in showerhead 453 combine with a silicon-containing precursor arriving through the small holes 455 originating from hollow volumes 451. Though substrate processing region 470 may be equipped to support a plasma for other processes such as curing, no plasma is present during the growth of the exemplary film.

A plasma may be ignited either in chamber plasma region 420 above showerhead 453 or substrate processing region 470 below showerhead 453. A plasma is present in chamber plasma region 420 to produce the radical-oxygen precursors from an inflow of a moisture. An AC voltage typically in the radio frequency (RF) range is applied between the conductive top portion 421 of the processing chamber and showerhead 453 to ignite a plasma in chamber plasma region 420 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 470 is turned on to either cure a film or clean the interior surfaces bordering substrate processing region 470. A plasma in substrate processing region 470 is ignited by applying an AC voltage between showerhead 453 and the pedestal or bottom of the chamber. A cleaning gas may be introduced into substrate processing region 470 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

The chamber plasma region or a region in an RPS may be referred to as a remote plasma region. In embodiments, the radical precursor (e.g. a radical-nitrogen precursor) is created in the remote plasma region and travels into the substrate processing region where the carbon-free silicon-containing precursor is excited by the radical precursor. In embodiments, the carbon-free silicon-containing precursor is excited only by the radical precursor. Plasma power may essentially be applied only to the remote plasma region, in embodiments, to ensure that the radical precursor provides the dominant excitation to the carbon-free silicon-containing precursor.

In embodiments employing a chamber plasma region, the excited plasma effluents are generated in a section of the substrate processing region partitioned from a deposition region. The deposition region, also known herein as the substrate processing region, is where the plasma effluents mix and react with the carbon-free silicon-containing precursor to deposit the silicon-oxygen-and-nitrogen layer on a deposition substrate (e.g., a semiconductor wafer). The excited plasma effluents may also be accompanied by inert gases (in the exemplary case, argon). The carbon-free silicon-containing precursor does not pass through a plasma before entering the substrate plasma region, in embodiments. The substrate processing region may be described herein as “plasma-free” during the growth of the silicon-oxygen-and-nitrogen-containing layer. “Plasma-free” does not necessarily mean the region is devoid of plasma. Ionized species and free electrons created within the plasma region do travel through pores (apertures) in the partition (showerhead) but the carbon-free silicon-containing precursor is not substantially excited by the plasma power applied to the plasma region. The borders of the plasma in the chamber plasma region are hard to define and may encroach upon the substrate processing region through the apertures in the showerhead. In the case of an inductively-coupled plasma, a small amount of ionization may be effected within the substrate processing region directly. Furthermore, a low intensity plasma may be created in the substrate processing region without eliminating desirable features of the forming film. All causes for a plasma having much lower intensity ion density than the chamber plasma region (or a remote plasma region, for that matter) during the creation of the excited plasma effluents do not deviate from the scope of “plasma-free” as used herein.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. “Silicon oxide” is used herein as a shorthand for and interchangeably with a silicon-and-oxygen-containing material. As such, silicon oxide may include concentrations of other elemental constituents such as nitrogen, hydrogen, carbon and the like. In some embodiments, silicon oxide films produced using the methods disclosed herein consist essentially of silicon and oxygen. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas may be a combination of two or more gases. A “radical precursor” is used to describe plasma effluents (a gas in an excited state which is exiting a plasma) which participate in a reaction to either remove material from or deposit material on a surface. A “radical-hydrogen precursor” is a radical precursor which contains hydrogen and a “radical-nitrogen precursor” contains nitrogen. Hydrogen may be present in a radical-nitrogen precursor and nitrogen may be present in a radical-hydrogen precursor. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a silicon oxide layer on a substrate in a plasma- free substrate processing region in a substrate processing chamber, the method comprising:
flowing an oxygen-containing precursor into a plasma region to produce a radical-oxygen precursor, wherein the oxygen-containing precursor comprises H₂O;
combining the radical-oxygen precursor with a silicon-containing precursor in the plasma-free substrate processing region, wherein the silicon-containing precursor contains nitrogen; and
depositing a silicon-oxygen-and-nitrogen-containing layer on the substrate.

2. The method of claim 1 wherein further comprising annealing the silicon-oxygen-and-nitrogen-containing layer at an annealing temperature in an oxygen-containing atmosphere to increase the oxygen-content and decrease the nitrogen-content to form a silicon oxide layer.

3. The method of claim 2 wherein the annealing temperature is between about 500° C. and about 1100° C. and the oxygen-containing atmosphere comprises at least one of O₂, O₃, H₂O, H₂O₂, NO, NO₂, N₂O and radical species derived therefrom.

4. The method of claim 1 wherein the silicon-oxygen-and-nitrogen-containing layer is initially flowable following deposition.

5. The method of claim 1 wherein the silicon-oxygen-and-nitrogen-containing layer is initially flowable following deposition while the substrate temperature is below or about 200° C.

6. The method of claim 1 wherein the plasma region is in a remote plasma system (RPS) located outside the substrate processing.

7. The method of claim 1 wherein the oxygen-containing precursor further comprises NH₃.

8. The method of claim 1 wherein a deposition rate of the silicon-oxygen-and-nitrogen-containing layer is greater than or about 2000 Å/min.

9. The method of claim 1 wherein a deposition rate of the silicon-oxygen-and-nitrogen-containing layer is greater than or about 3000 Å/min.

10. The method of claim 1 wherein a deposition rate of the silicon-oxygen-and-nitrogen-containing layer is greater than or about 4000 Å/min.

11. The method of claim 1 wherein the silicon-oxygen-and-nitrogen-containing layer comprises a carbon-free Si—O—N—H layer.

12. The method of claim 1 wherein the oxygen-containing precursor further comprises at least one of O₂, O₃, H₂O₂, NO, NO₂ and N₂O.

13. The method of claim 1 wherein the substrate is patterned with a trench having a width of about 50 nm or less and the silicon-oxygen-and-nitrogen layer is flowable during deposition and fills the trench.

14. The method of claim 13 wherein the silicon oxide layer in the trench is substantially void-free.

15. The method of claim 1 wherein the plasma region is a partitioned portion of the substrate processing chamber separated from the plasma-free substrate processing region by a showerhead.

16. The method of claim 1 further comprising an operation of curing the film in an ozone-containing atmosphere while maintaining a substrate temperature below about 400° C.

17. The method of claim 1 wherein the silicon-containing precursor is carbon-free.

18. The method of claim 1 wherein the silicon-containing precursor comprises at least one of H₂N(SiH₃), HN(SiH₃)₂ and N(SiH₃)₃.
